(19) United States
(12) Patent Application Publication
(10) Pub. No.: US 2025/0284212 A1
(43) Pub. Date: Sep. 11, 2025

(54) OPTICAL SYSTEM, LITHOGRAPHY APPARATUS COMPRISING AN OPTICAL SYSTEM, AND ARRANGEMENT COMPRISING AN OPTICAL SYSTEM

(71) Applicant: Carl Zeiss SMT GmbH, Oberkochen (DE)

(72) Inventor: Ralf KIESEL, Gaildorf (DE)

(21) Appl. No.: 19/214,266

(22) Filed: May 21, 2025

Related U.S. Application Data
(63) Continuation of application No. PCT/EP2023/082991, filed on Nov. 24, 2023.

(30) Foreign Application Priority Data
Nov. 24, 2022 (DE) 10 2022 212 537.1

(51) Int. Cl. G03F 7/00

(52) U.S. Cl. CPC G03F 7/70841; G03F 7/70525; G03F 7/70991

(57) ABSTRACT

An optical system for a lithography apparatus, comprises: a vacuum housing under vacuum, in which a number of optical elements for guiding radiation in the optical system and a number of actuator/sensor devices assigned to the optical elements are arranged; a vacuum-tight housing that is separate from the vacuum housing and under atmospheric pressure; and an electrical vacuum feedthrough that connects the vacuum housing and the vacuum-tight housing and serves to feed at least one electrical connection connected to at least one of the actuator/sensor devices from the vacuum-tight housing into the vacuum housing. An optical transceiver module for converting optical signals into electrical signals, which is connectable to a controller via at least one optical waveguide, is arranged in the interior of the vacuum-tight housing and is electrically connected to the electrical vacuum feedthrough.

### CROSS-REFERENCE TO RELATED APPLICATIONS

The present application is a continuation of, and claims benefit under 35 USC 120 to, international application No. PCT/EP2023/082991, filed Nov. 24, 2023, which claims benefit under 35 USC 119 of German Application No. 10 2022 212 537.1, filed Nov. 24, 2022. The entire disclosure of each of these applications is incorporated by reference herein.

### FIELD

The present disclosure relates to an optical system, a lithography apparatus having such an optical system, and an arrangement having such an optical system.

### BACKGROUND

Microlithography is used for producing microstructured components, such as for example integrated circuits. The microlithography process is performed using a lithography apparatus, which comprises an illumination system and a projection system. The image of a mask (reticle) illuminated via the illumination system is projected via the projection system onto a substrate, for example a silicon wafer, which is coated with a light-sensitive layer (photoresist) and arranged in the image plane of the projection system, in order to transfer the mask structure to the light-sensitive coating of the substrate.

Driven by the desire for ever smaller structures in the production of integrated circuits, EUV lithography apparatuses which use light with a wavelength in the range of 0.1 nanometer (nm) to 30 nm, for example 13.5 nm, are currently being developed. Since most materials absorb light at this wavelength, it is generally desirable in such EUV lithography apparatuses to use reflective optics units, i.e. mirrors, instead of refractive optics units, i.e. lens elements, as used previously.

A multiplicity of actuator/sensor devices, such as sensors and actuators, are often installed in an optical system of a lithography apparatus. In general, an actuator/sensor device is suitable for displacing an optical element, for example a mirror, assigned to the actuator/sensor device and/or for detecting a parameter of the assigned optical element, for instance a position of the assigned optical element or a temperature of the assigned optical element.

For control and evaluation purposes, the actuator/sensor devices of the optical system are usually connected to a controller that is arranged outside of the vacuum housing of the optical system. For example, the external controller is arranged in a gray room or a clean room. For example, the external controller is configured to provide control signals for the actuator/sensor devices and evaluate data received from the actuator/sensor devices.

Using a copper-bound transmission for the data transfer between the external controller and the actuator/sensor devices in the vacuum housing of the optical system can result in a relatively low data rate, for example in comparison with optical data transfer methods. By contrast, an optical data transfer method can provide relatively high bit rates over relatively long distances, with little relatively susceptibility to disturbances.

However, an optical transceiver module would typically be used in the vacuum in the event of optical data transfer to the actuator/sensor devices in the vacuum of the optical system via optical waveguides. In comparison with purely electrical data transfer systems, for example based on copper, such an optical transceiver module generally has a higher failure probability and generally a shorter service life. However, maintenance or replacement of an optical transceiver module arranged in the vacuum housing of the optical system could be relatively complicated. For example, the vacuum in the vacuum housing could have to be vented and reestablished following the repair or replacement of the optical transceiver module, which could involve substantial effort and a long machine downtime of the optical system.

### SUMMARY

The present disclosure seeks to provide an improved optical system with increased availability.

According to a first aspect, an optical system for a lithography apparatus is proposed, the optical system comprising:
a vacuum housing under vacuum, in which a number of optical elements for guiding radiation in the optical system and a number of actuator/sensor devices assigned to the optical elements are arranged;
a vacuum-tight housing that is separate from the vacuum housing and under atmospheric pressure; and
an electrical vacuum feedthrough that connects the vacuum housing and the vacuum-tight housing and serves to feed at least one electrical connection connected to at least one of the actuator/sensor devices from the vacuum-tight housing into the vacuum housing, wherein an optical transceiver module for converting optical signals into electrical signals, which is connectable to a controller via at least one optical waveguide, is arranged in the interior of the vacuum-tight housing and electrically connected to the electrical vacuum feedthrough.

Use of the optical transceiver module in the vacuum-tight housing, which is provided in encapsulated fashion at or in the vacuum housing of the optical system, can allow for the use of an optical data transfer using optical waveguides (optical fibers) between the external controller and the actuator/sensor devices of the optical system, as far as the vacuum housing. An electrical data transfer, for example based on copper, can be used in the vacuum housing downstream of the optical transceiver module and up to the actuator/sensor devices. In comparison with electrical connections, optical waveguides typically offer higher bit rates over long distances, with relatively little susceptibility to disturbances. In the present case, the optical transceiver module can be implemented at the atmosphere/vacuum boundary as transition point between optical data transfer and wired data transfer.

Since the transceiver module is arranged on the atmospheric side, and hence not in the vacuum, maintenance and replacement thereof can be much simpler in comparison with a potential arrangement in the vacuum housing.

Data can be transferred between the controller and the actuator/sensor devices via an optical transfer method on the atmospheric side, whereas they can be transferred in the vacuum via a wired transfer method. The use of the optical transceiver module, arranged in the encapsulated vacuum-tight housing in or at the vacuum housing of the optical system, can bring about a beneficial balance between fast and failsafe data transfer and enhanced ability to service the optical transceiver module.

The optical system can be a projection optics unit of the lithography apparatus or projection exposure apparatus. However, the optical system may also be an illumination system. The projection exposure apparatus may be an EUV lithography apparatus. EUV stands for “extreme ultraviolet” and refers to a wavelength of the operating light of between 0.1 nm and 30 nm. The projection exposure apparatus may also be a DUV lithography apparatus. DUV stands for “deep ultraviolet” and refers to a wavelength of the operating light of between 30 nm and 465 nm.

For example, the respective actuator/sensor device is an actuator (or actuating element) for actuating an optical element, a sensor for sensing an optical element or surroundings within the optical system, or an actuator and sensor device for actuating and sensing within the optical system. For example, the sensor is a position sensor. Optionally, the actuator is an actuator using the electrostrictive effect or an actuator using the piezoelectric effect, for example a PMN actuator (PMN; lead magnesium niobate) or a PZT actuator (PZT; lead zirconate titanate). For example, the actuator is configured to actuate an optical element of the optical system. Examples of such an optical element include lens elements, mirrors and adaptive mirrors.

The optical waveguide may also be referred to as an optical fiber and is provided as a light-guiding cable or as a fiber-optic cable for example. For example, an electrical vacuum feedthrough is known from documents U.S. Pat. Nos. 4,982,055A1, 6,305,975B1 and WO14076303A1.

According to an embodiment, the optical transceiver module takes the form of a pluggable optical transceiver module.

According to an embodiment, a plug-in module is arranged in the interior of the vacuum-tight housing. The optical transceiver module can be plugged into the plug-in module. In this case, the plug-in module is electrically connected to the electrical vacuum feedthrough.

The embodiment of the pluggable optical transceiver module can be relatively easy to service. In the event of a defect of the pluggable optical transceiver module, the latter can be plugged out of the plug-in module on the atmospheric side and repaired or optionally replaced. The vacuum in the vacuum housing of the optical system can remain untouched by such maintenance or repair. On the other hand, optical data transfer can be used to a point as close as possible to the vacuum in the vacuum housing as a result of using the transceiver module.

According to an embodiment, a driver unit for amplifying the electrical signals provided by the optical transceiver module is arranged in the interior of the vacuum-tight housing. Optionally, the driver unit is connected between the optical transceiver module and the electrical vacuum feedthrough. For example, the driver unit is used in a manner dependent on the length in the vacuum of the electrical connection to the respective actuator/sensor device, and its gain is set accordingly.

According to an embodiment, a printed circuit board is arranged in the interior of the vacuum-tight housing. Optionally, the driver unit is arranged on the printed circuit board. The printed circuit board is electrically connected to the plug-in module. In this case, the driver unit can take the form of an integrated circuit that is arranged or integrated on the printed circuit board.

According to an embodiment, a printed circuit board, which is electrically connected to the plug-in module, fed through the electrical vacuum feedthrough and electrically connected to at least one of the actuator/sensor devices in the vacuum housing, is arranged in the interior of the vacuum-tight housing. This embodiment can mean that the printed circuit board itself is guided through the electrical vacuum feedthrough and can be used in turn on the side of the vacuum, for example for the placement of a driver unit or a subset of the actuator/sensor devices.

According to an embodiment, the printed circuit board has at least one pliable region. The pliable region of the printed circuit board may also be referred to as a flexible region. The printed circuit board may also be referred to as circuit board.

According to an embodiment, a driver unit for amplifying the electrical signals provided by the optical transceiver module is arranged in the vacuum housing. Optionally, the driver unit is electrically connected to the electrical connection fed through the electrical vacuum feedthrough and to the at least one actuator/sensor device.

According to an embodiment, the length of the electrical connection between the electrical vacuum feedthrough and the at least one connected actuator/sensor device is at least three times longer, such as at least five times longer, for example at least ten times longer, and for example at least twenty times longer, than the length of the optical waveguide between the optical transceiver module and the external controller.

According to an embodiment, the electrical connection comprises a copper line that is arranged in the vacuum housing. The copper line may take the form of a copper cable with a plug, wherein the plug thereof can be plugged into the electrical vacuum feedthrough.

According to an embodiment, the vacuum-tight housing takes the form of an encapsulated region in the vacuum housing.

In an embodiment, the vacuum-tight housing may take the form of an encapsulated region directly at the vacuum housing.

According to an embodiment, the vacuum housing is designed for a pressure of 1013.25 hectoPascal (hPa) to 10⁻³ hPa, or a pressure of 10⁻³ to 10⁻⁸ hPa, or a pressure of 10⁻⁸ to 10⁻¹¹ hPa in its interior.

By contrast, the vacuum-tight housing is designed for atmospheric pressure in its interior and for it to be sealed vis-à-vis the vacuum in the vacuum housing of the optical system.

Atmospheric pressure may also be referred to as pressure of the atmosphere. Atmospheric pressure is the pressure in the ambient air at the Earth's surface or in the vicinity of the latter.

According to an embodiment, the optical system takes the form of an illumination optics unit or the form of a projection optics unit of a lithography apparatus.

According to a second aspect, a lithography apparatus is proposed, which comprises an optical system according to the first aspect or according to one of the embodiments of the first aspect.

According to a third aspect, an arrangement is proposed, which comprises an optical system according to the first aspect or according to one of the embodiments of the first aspect and a controller arranged in a gray room or in a clean room. In this case, the optical transceiver module of the optical system and the controller are connected for data transfer via at least one optical waveguide.

The embodiments described for the proposed optical system apply accordingly to the proposed lithography apparatus and the proposed arrangement, and vice versa.

Furthermore, the definitions and explanations in relation to the optical system also apply accordingly to the proposed method.

“A(n)” should not necessarily be understood as a restriction to exactly one element in the present case. Rather, there may also be multiple elements, for example two, three or more. Nor should any other numeral used here be understood to the effect that there is a restriction to exactly the stated number of elements. Rather, numerical deviations upward and downward are possible, unless indicated otherwise.

Further possible implementations of the disclosure also encompass not explicitly mentioned combinations of features or embodiments that are described above or hereinafter with respect to the exemplary embodiments. A person skilled in the art will also add individual aspects as improvements or supplementations to the respective basic form of the disclosure.

Further configurations and aspects of the disclosure are the subject of the dependent claims and of the exemplary embodiments of the disclosure that will be described hereinafter. The disclosure is explained in greater detail hereinafter on the basis of embodiments with reference to the accompanying figures.

### BRIEF DESCRIPTION OF THE DRAWINGS

FIG. 1 shows a schematic meridional section of a projection exposure apparatus for EUV projection lithography;

FIG. 2 shows a schematic illustration of a first embodiment of an optical system;

FIG. 3 shows a schematic illustration of a second embodiment of an optical system; and

FIG. 4 shows a schematic illustration of a third embodiment of an optical system.

### DETAILED DESCRIPTION

In the figures, identical or functionally identical elements have been provided with the same reference signs, unless indicated otherwise. It should also be noted that the illustrations in the figures are not necessarily true to scale.

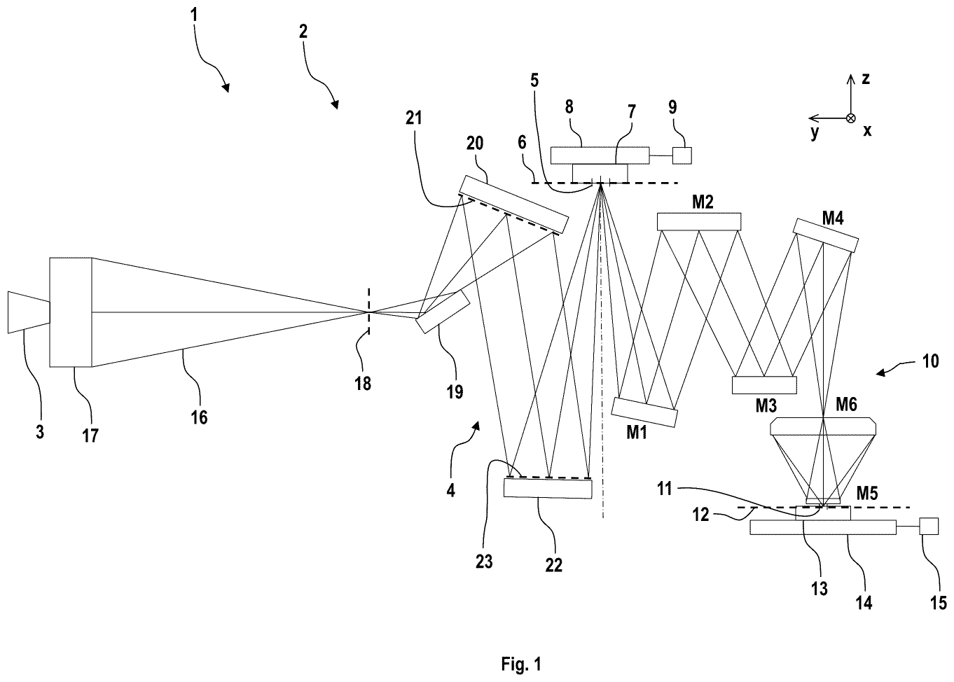

FIG. 1 shows an embodiment of a projection exposure apparatus 1 (lithography apparatus), for example an EUV lithography apparatus. In addition to a light source or radiation source 3, an embodiment of an illumination system 2 of the projection exposure apparatus 1 has an illumination optics unit 4 for illuminating an object field 5 in an object plane 6. In an alternative embodiment, the light source 3 may also be provided as a module separate from the rest of the illumination system 2. In this case, the illumination system 2 does not comprise the light source 3.

A reticle 7 arranged in the object field 5 is exposed. The reticle 7 is held by a reticle holder 8. The reticle holder 8 is displaceable by way of a reticle displacement drive 9, for example in a scanning direction.

FIG. 1 shows, for explanation purposes, a Cartesian coordinate system with an x-direction x, a y-direction y, and a z-direction z. The x-direction x runs perpendicularly into the plane of the drawing. The y-direction y runs horizontally, and the z-direction z runs vertically. The scanning direction runs in the y-direction y in FIG. 1. The z-direction z runs perpendicularly to the object plane 6.

The projection exposure apparatus 1 comprises a projection optics unit 10. The projection optics unit 10 serves for imaging the object field 5 into an image field 11 in an image plane 12. The image plane 12 extends parallel to the object plane 6. In an alternative, an angle that differs from 0° is also possible between the object plane 6 and the image plane 12.

A structure on the reticle 7 is imaged onto a light-sensitive layer of a wafer 13 arranged in the region of the image field 11 in the image plane 12. The wafer 13 is held by a wafer holder 14. The wafer holder 14 is displaceable by way of a wafer displacement drive 15, for example in the y-direction y. The displacement firstly of the reticle 7 by way of the reticle displacement drive 9 and secondly of the wafer 13 by way of the wafer displacement drive 15 may be implemented so as to be mutually synchronized.

The light source 3 is an EUV radiation source. The light source 3 emits EUV radiation 16, which is also referred to below as used radiation, illumination radiation or illumination light. The used radiation 16 can have a wavelength in the range of between 5 nm and 30 nm. The light source 3 may be a plasma source, for example an LPP (laser produced plasma) source or a GDPP (gas discharge produced plasma) source. It may also be a synchrotron-based radiation source. The light source 3 may be a free electron laser (FEL).

The illumination radiation 16 emanating from the light source 3 is focused by a collector 17. The collector 17 may be a collector with one or more ellipsoidal and/or hyperboloidal reflection surfaces. The illumination radiation 16 may be incident on the at least one reflection surface of the collector 17 with grazing incidence (GI), i.e. at angles of incidence of greater than 45°, or with normal incidence (NI), i.e. at angles of incidence of less than 45°. The collector 17 may be structured and/or coated, both to optimize its reflectivity for the used radiation and to suppress extraneous light.

Downstream of the collector 17, the illumination radiation 16 propagates through an intermediate focus in an intermediate focal plane 18. The intermediate focal plane 18 can represent a separation between a radiation source module, comprising the light source 3 and the collector 17, and the illumination optics unit 4.

The illumination optics unit 4 comprises a deflection mirror 19 and, disposed downstream thereof in the beam path, a first facet mirror 20. The deflection mirror 19 may be a plane deflection mirror or, in an alternative to that, a mirror with a beam-influencing effect going beyond the pure deflection effect. In an alternative to that or in addition, the deflection mirror 19 may be in the form of a spectral filter that separates a used light wavelength of the illumination radiation 16 from extraneous light at a different wavelength. Should the first facet mirror 20 be arranged in a plane of the illumination optics unit 4 which is optically conjugate to the object plane 6 as a field plane, this facet mirror is also referred to as a field facet mirror. The first facet mirror 20 comprises a multiplicity of individual first facets 21, which can also be referred to as field facets. Only some of these first facets 21 are illustrated in FIG. 1 by way of example.

The first facets 21 may take the form of macroscopic facets, for example as rectangular facets or as facets with an arc-shaped or part-circular edge contour. The first facets 21 may take the form of plane facets or, in an alternative to that, convexly or concavely curved facets.

As is known for example from DE 10 2008 009 600 A1, the first facets 21 themselves may each also be composed of a multiplicity of individual mirrors, for example a multiplicity of micromirrors. The first facet mirror 20 may take the form of a microelectromechanical system (MEMS system) for example. For details, reference is made to DE 10 2008 009 600 A1.

The illumination radiation 16 propagates horizontally, i.e. in the y-direction y, between the collector 17 and the deflection mirror 19.

In the beam path of the illumination optics unit 4, a second facet mirror 22 is disposed downstream of the first facet mirror 20. Should the second facet mirror 22 be arranged in a pupil plane of the illumination optics unit 4, it is also referred to as a pupil facet mirror. The second facet mirror 22 may also be spaced apart from a pupil plane of the illumination optics unit 4. In this case, the combination of the first facet mirror 20 and the second facet mirror 22 is also referred to as a specular reflector. Specular reflectors are known from US 2006/0132747 A1, EP 1 614 008 B1, and U.S. Pat. No. 6,573,978.

The second facet mirror 22 comprises a plurality of second facets 23. In the case of a pupil facet mirror, the second facets 23 are also referred to as pupil facets.

The second facets 23 may likewise be macroscopic facets, which may for example have a round, rectangular or else hexagonal boundary, or alternatively may be facets composed of micromirrors. For details, reference is also made to DE 10 2008 009 600 A1.

The second facets 23 may have plane reflection surfaces or, in an alternative to that, convexly or concavely curved reflection surfaces.

The illumination optics unit 4 thus forms a doubly faceted system. This fundamental principle is also referred to as a fly's eye integrator.

It may be desirable to arrange the second facet mirror 22 not exactly within a plane that is optically conjugate to a pupil plane of the projection optics unit 10. For example, the second facet mirror 22 may be arranged so as to be tilted in relation to a pupil plane of the projection optics unit 10, as described for example in DE 10 2017 220 586 A1.

The second facet mirror 22 is used to image the individual first facets 21 into the object field 5. The second facet mirror 22 is the last beam-shaping mirror or else actually the last mirror for the illumination radiation 16 in the beam path upstream of the object field 5.

In a further embodiment (not illustrated) of the illumination optics unit 4, a transfer optics unit contributing for example to the imaging of the first facets 21 into the object field 5 may be arranged in the beam path between the second facet mirror 22 and the object field 5. The transfer optics unit may have exactly one mirror or, in an alternative to that, two or more mirrors, which are arranged one behind another in the beam path of the illumination optics unit 4. The transfer optics unit may for example comprise one or two normal-incidence mirrors (NI mirrors) and/or one or two grazing-incidence mirrors (GI mirrors).

In the embodiment shown in FIG. 1, the illumination optics unit 4 has exactly three mirrors downstream of the collector 17, specifically the deflection mirror 19, the first facet mirror 20, and the second facet mirror 22.

In a further embodiment of the illumination optics unit 4, the deflection mirror 19 may also be omitted, and so the illumination optics unit 4 may then have exactly two mirrors downstream of the collector 17, specifically the first facet mirror 20 and the second facet mirror 22.

The imaging of the first facets 21 into the object plane 6 via the second facets 23 or using the second facets 23 and a transfer optics unit is, as a rule, only approximate imaging.

The projection optics unit 10 comprises a plurality of mirrors Mi, which are consecutively numbered in accordance with their arrangement in the beam path of the projection exposure apparatus 1.

In the example illustrated in FIG. 1, the projection optics unit 10 comprises six mirrors M1 to M6. Alternatives with four, eight, ten, twelve or any other number of mirrors Mi are likewise possible. The projection optics unit 10 is a doubly obscured optical unit. The penultimate mirror M5 and the last mirror M6 each have a passage opening for the illumination radiation 16. The projection optics unit 10 has an image-side numerical aperture which is greater than 0.5 and which may also be greater than 0.6 and which, for example, may be 0.7 or 0.75.

Reflection surfaces of the mirrors Mi may be in the form of free-form surfaces without an axis of rotational symmetry. In an alternative to that, the reflection surfaces of the mirrors Mi may be designed as aspherical surfaces with exactly one axis of rotational symmetry of the reflection surface shape. Just like the mirrors of the illumination optics unit 4, the mirrors Mi may have highly reflective coatings for the illumination radiation 16. These coatings may be designed as multilayer coatings, for example with alternating layers of molybdenum and silicon.

The projection optics unit 10 has a large object-image offset in the y-direction y between a y-coordinate of a center of the object field 5 and a y-coordinate of the center of the image field 11. This object-image offset in the y-direction y can be of approximately the same magnitude as a z-distance between the object plane 6 and the image plane 12.

For example, the projection optics unit 10 may have an anamorphic design. It has for example different imaging scales βx, βy in the x- and y-directions x, y. The two imaging scales βx, βy of the projection optics unit 10 can be (βx, βy)=(+/−0.25, +/−0.125). A positive imaging scale β means imaging without image inversion. A negative sign for the imaging scale β means imaging with image inversion.

The projection optics unit 10 consequently leads to a reduction in size with a ratio of 4:1 in the x-direction x, i.e. in a direction perpendicular to the scanning direction.

The projection optics unit 10 leads to a reduction in size of 8:1 in the y-direction y, i.e. in the scanning direction.

Other imaging scales are likewise possible. Imaging scales with the same sign and the same absolute value in the x-direction x and y-direction y are also possible, for example with absolute values of 0.125 or of 0.25.

The number of intermediate image planes in the x-direction x and in the y-direction y in the beam path between the object field 5 and the image field 11 can be the same or can differ, depending on the embodiment of the projection optics unit 10. Examples of projection optics units with different numbers of such intermediate images in the x-direction x and y-direction y are known from US 2018/0074303 A1.

In each case, one of the second facets 23 is assigned to exactly one of the first facets 21 for forming in each case an illumination channel for illuminating the object field 5. This may yield for example illumination according to the Köhler principle. The far field is decomposed into a multiplicity of object fields 5 with the aid of the first facets 21. The first facets 21 create a plurality of images of the intermediate focus on the second facets 23 respectively assigned to them.

The first facets 21 are each imaged onto the reticle 7 by an assigned second facet 23 and overlaid over one another for the purpose of illuminating the object field 5. The illumination of the object field 5 is for example as homogeneous as possible. It can have a uniformity error of less than 2%. Field uniformity may be achieved by overlaying different illumination channels.

The illumination of the entrance pupil of the projection optics unit 10 can be defined geometrically by an arrangement of the second facets 23. The intensity distribution in the entrance pupil of the projection optics unit 10 can be set by selecting the illumination channels, for example the subset of the second facets 23, which guide light. This intensity distribution is also referred to as illumination setting or illumination pupil filling.

A likewise preferred pupil uniformity in the region of portions of an illumination pupil of the illumination optics unit 4 which are illuminated in a defined manner may be achieved by a redistribution of the illumination channels.

Further aspects and details of the illumination of the object field 5 and for example of the entrance pupil of the projection optics unit 10 are described below.

The projection optics unit 10 may have for example a homocentric entrance pupil. The latter may be accessible. It may also be inaccessible.

The entrance pupil of the projection optics unit 10 regularly cannot be exactly illuminated with the second facet mirror 22. In the case of an imaging process of the projection optics unit 10 that images the center of the second facet mirror 22 telecentrically onto the wafer 13, the aperture rays often do not intersect at a single point. However, it is possible to find an area in which the spacing of the aperture rays that is determined in pairs becomes minimal. This area represents the entrance pupil or an area conjugate thereto in real space. For example, this area exhibits a finite curvature.

It may be the case that the projection optics unit 10 has different positions of the entrance pupil for the tangential beam path and for the sagittal beam path. In this case, an imaging element, for example an optical structural element, of the transfer optics unit should be provided between the second facet mirror 22 and the reticle 7. Using this optical element, the different positions of the tangential entrance pupil and the sagittal entrance pupil may be taken into account.

In the arrangement of the components of the illumination optics unit 4 illustrated in FIG. 1, the second facet mirror 22 is arranged in an area conjugate to the entrance pupil of the projection optical unit 10. The first facet mirror 20 is arranged so as to be tilted with respect to the object plane 6. The first facet mirror 20 is arranged so as to be tilted with respect to an arrangement plane defined by the deflection mirror 19. The first facet mirror 20 is arranged so as to be tilted with respect to an arrangement plane defined by the second facet mirror 22.

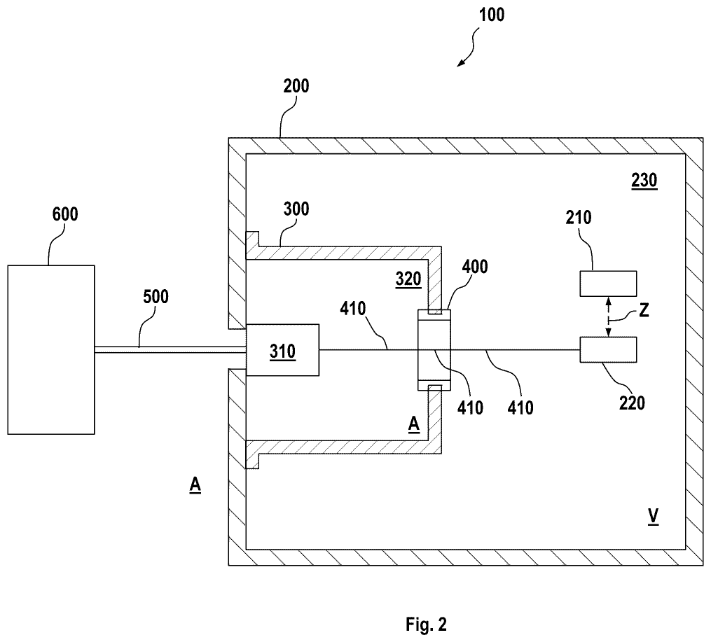

FIG. 2 shows a schematic illustration of a first embodiment of an optical system 100 for a lithography apparatus or projection exposure apparatus 1, as shown in FIG. 1, for example. Additionally, the optical system 100 in FIG. 2 may also be used in a DUV lithography apparatus, for example.

The optical system 100 in FIG. 2 comprises a vacuum housing 200 under vacuum V. A number of optical elements 210 for guiding radiation in the optical system 100 and a number of actuator/sensor devices 220 assigned to the optical elements 210 are arranged in the interior 230 of the vacuum housing 200. Without loss of generality, FIG. 2 shows an actuator/sensor device 220, which is assigned to an optical element 210. In FIG. 2, this assignment is illustrated by reference sign Z.

Further, the optical system 100 in FIG. 2 comprises a vacuum-tight housing 300 that is separate from the vacuum housing 200 and under atmospheric pressure A. Optionally, the vacuum-tight housing 300 takes the form of an encapsulated region in the vacuum housing 200 (see FIG. 2).

Moreover, the optical system 100 comprises an electrical vacuum feedthrough 400 that connects the vacuum housing 200 and the vacuum-tight housing 300. The electrical vacuum feedthrough 400 is suitable for feeding an electrical connection 410 from the vacuum-tight housing 300 into the vacuum housing 200. The actuator/sensor device 220 is electrically connected to the electrical connection 410. The electrical connection 410 for example comprises a number of electrical conductors, for example based on copper.

An optical transceiver module 310 for converting optical signals into electrical signals, and vice versa, is arranged in the interior 320 of the vacuum-tight housing 300. The optical transceiver module 310 can be coupled by way of an optical waveguide 500 to a controller 600 that is arranged outside of the vacuum housing 200 of the optical system 100.

The controller 600 is provided externally to the optical system 100—as explained—and for example externally to the vacuum housing 200 of the optical system 100. The controller 600 is configured to provide control signals for the actuator/sensor device 220. The control signals from the controller 600 are transferred to the connected actuator/sensor device 220 via the optical waveguide 500, the optical transceiver module 310, the electrical vacuum feedthrough 400 and the electrical connection 410. Moreover, the controller 600 is configured to receive signals from the actuator/sensor devices 220 via the path specified.

Use of the optical transceiver module 310 in the vacuum-tight housing 300, which is provided in encapsulated fashion at or in the vacuum housing 200 of the optical system 100, allows the use of optical waveguides 500 for data transfer between the external controller 600 and the actuator/sensor device 220 of the optical system 100, as far as the vacuum housing 200. In comparison with electrical connections, for example based on copper, optical waveguides 500 offer higher bit rates over long distances, with very little susceptibility to disturbances. In the present case, the optical transceiver module 310 thus is implemented at the atmospheric pressure/vacuum boundary as transition site between optical data transfer and wired data transfer.

Since the transceiver module 310 is arranged on the atmospheric side A, maintenance and replacement thereof is much simpler in comparison with a potential provision in the vacuum V in the vacuum housing 200. Accordingly, the data could be transferred between the controller 600 and the actuator/sensor devices 200 via an optical transfer method on the atmospheric side A, whereas they are transferred in the vacuum V via a wired transfer method. Overall, the use of the optical transceiver module 310, provided in the encapsulated vacuum-tight housing 300 in or at the vacuum housing 200 of the optical system 100, offers optimal balance between fast and failsafe data transfer and optimal ability to service the optical transceiver module 310.

Optionally, the length of the electrical connection 410 between the electrical vacuum feedthrough 400 and the connected actuator/sensor device 220 is at least three times longer, such as at least five times longer, for example at least ten times longer, and for example at least twenty times longer, than the length of the optical waveguide 500 between the optical transceiver module 310 and the external controller 600.

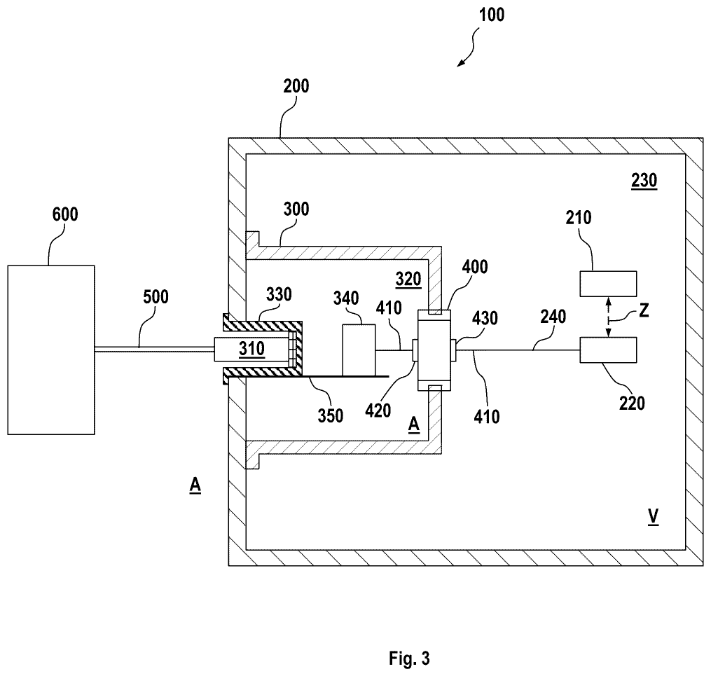

FIG. 3 illustrates a schematic illustration of a second embodiment of an optical system 100. The second embodiment according to FIG. 3 is based substantially on the first embodiment according to FIG. 2.

In the second embodiment according to FIG. 3, the optical transceiver module 310 takes the form of a pluggable module. Moreover, a plug-in module 330 is provided in the interior 320 of the vacuum-tight housing 300.

According to FIG. 3, the optical transceiver module 310 can be plugged into the plug-in module 330. Here, the plug-in module 330 is electrically connected to the electrical vacuum feedthrough 400. To this end, a printed circuit board 350 is provided in the second embodiment according to FIG. 3.

Further, a driver unit 340 for amplifying the electrical signals provided by the optical transceiver module 310 is provided in the interior 320 of the vacuum-tight housing 300 in FIG. 3. The driver unit 340 is connected between the optical transceiver module 310 and the electrical vacuum feedthrough 400 and optionally arranged on the printed circuit board 350.

In the second embodiment according to FIG. 3, the control signals are provided by the external controller 600 and transferred by the optical waveguide 500 to the optical transceiver module 310, which is plugged into the plug-in module 330. The optical transceiver module 310 converts the received optical signals into electrical signals and transmits the converted electrical signals from the plug-in module 330 to the driver unit 340 via the printed circuit board 350. The driver unit 340 amplifies the received electrical signals into amplified electrical signals, which are transmitted to the actuator/sensor device 220 via the electrical connection 410, which is fed through the electrical vacuum feedthrough 400. The driver unit 340 may comprise a protocol translation unit. Alternatively, a protocol translation unit may be disposed downstream of the driver unit 340. To this end, the electrical vacuum feedthrough 400 may comprise a plug 420 on the atmospheric side A and a further plug 430 on the vacuum side V. According to FIG. 3, a copper cable 240 used to transmit the electrical signals that were amplified by the driver unit 340 to the actuator/sensor device 220 is connected to the vacuum-side plug 430.

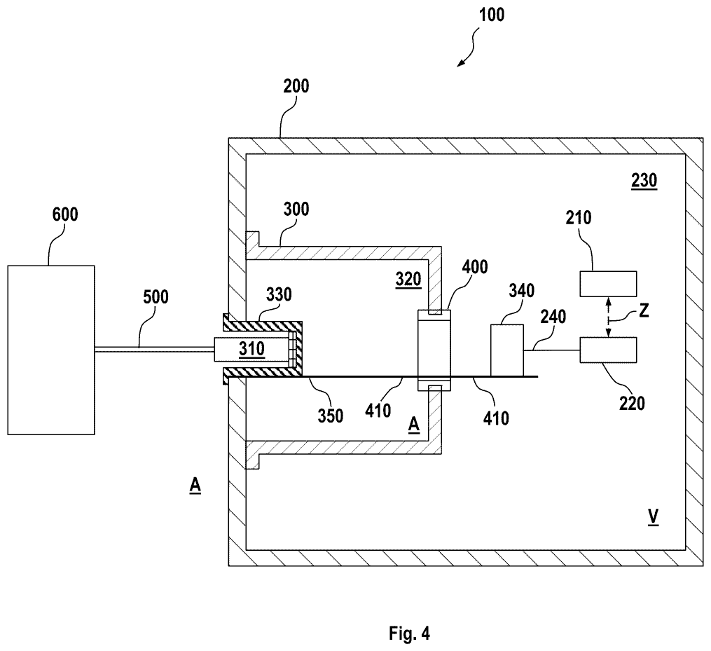

FIG. 4 shows a schematic illustration of a third embodiment of an optical system 100. The third embodiment according to FIG. 4 differs from the second embodiment according to FIG. 3 to the effect that the printed circuit board 350 in FIG. 4 is fed through the electrical vacuum feedthrough 400 and electrically connected to the actuator/sensor device 220 in the interior 230 of the vacuum housing 200. A further difference between the third embodiment according to FIG. 4 and the second embodiment according to FIG. 3 lies in the fact that according to FIG. 4 the driver unit 340 is arranged in the interior 230 of the vacuum housing 200. A copper cable 240 for data transfer is provided between the driver unit 340 that is arranged in the vacuum V and the actuator/sensor device 220.

Although the present disclosure has been described on the basis of exemplary embodiments, it is modifiable in diverse ways.

### LIST OF REFERENCE SIGNS

1 Projection exposure apparatus
2 Illumination system
3 Light source
4 Illumination optics unit
5 Object field
6 Object plane
7 Reticle
8 Reticle holder
9 Reticle displacement drive
10 Projection optics unit
11 Image field
12 Image plane
13 Wafer
14 Wafer holder
15 Wafer displacement drive
16 Illumination radiation
17 Collector
18 Intermediate focal plane
19 Deflection mirror
20 First facet mirror
21 First facet
22 Second facet mirror
23 Second facet
100 Optical system
200 Vacuum housing
210 Optical element
220 Actuator/sensor device
230 Interior of the vacuum housing
240 Copper cable
300 Vacuum-tight housing
310 Optical transceiver module
320 Interior of the vacuum-tight housing
330 Plug-in module
340 Driver unit
350 Printed circuit board
400 Electrical vacuum feedthrough
410 Electrical connection
420 Plug
430 Plug
500 Optical waveguide
600 Controller
A Atmospheric pressure
V Vacuum
Z Assignment

What is claimed is:

1. An optical system, comprising:
a vacuum housing configured to be under vacuum;
a number of optical elements in the vacuum housing, the number of optical elements configured to guide radiation in the optical system;
a number of actuator/sensor devices in the vacuum housing, the number of sensors assigned to the optical elements;
a vacuum-tight housing configured to be under atmospheric pressure, the vacuum-tight housing being separate from the vacuum housing;
an electrical vacuum feedthrough connecting the vacuum housing and the vacuum-tight housing, the electrical vacuum feedthrough configured to feed an electrical connection connected to at least one of the actuator/sensor devices from the vacuum housing into the vacuum-tight housing; and
an optical transceiver module in an interior of the vacuum-tight housing, the optical transceiver configured to convert optical signals into electrical signals, the optical transceiver being electrically connected to the electrical vacuum feedthrough, and the optical transceiver being connectable to a controller via an optical waveguide.

2. The optical system of claim 1, wherein the optical transceiver module comprises a pluggable optical transceiver module.

3. The optical system as claimed in claim 1, further comprising a plug-in module in the interior of the vacuum-tight housing, wherein the plug-in module is electrically connected to the electrical vacuum feedthrough, and the optical transceiver module is configured to be plugged into the plug-in module.

4. The optical system of claim 3, further comprising a driver unit in the interior of the vacuum-tight housing, wherein the driver unit is connected between the optical transceiver module and the electrical vacuum feedthrough, and the driver unit is configured to amplify the electrical signals provided by the optical transceiver module.

5. The optical system of claim 4, further comprising a printed circuit board in the interior of the vacuum-tight housing, wherein the printed circuit board is electrically connected to the plug-in module, and the driver unit is arranged on the printed circuit board.

6. The optical system of claim 4, further comprising a printed circuit board in the interior of the vacuum-tight housing, wherein the printed circuit board is electrically connected to the plug-in module, the printed circuit board passes through the electrical vacuum feedthrough, and the printed circuit board is electrically connected to at least one of the actuator/sensor devices.

7. The optical system of claim 1, further comprising a driver unit in the interior of the vacuum-tight housing, wherein the driver unit is connected between the optical transceiver module and the electrical vacuum feedthrough, and the driver unit is configured to amplify the electrical signals provided by the optical transceiver module.

8. The optical system of claim 1, further comprising the electrical connection.

9. The optical system of claim 8, further comprising a driver unit, wherein:
in the vacuum housing, the driver unit is connected to the electrical connection.

10. The optical system of claim 8, wherein the electrical connection comprises a copper line.

11. The optical system of claim 1, further comprising the controller, the optical waveguide, and the electrical connection.

12. The optical system of claim 11, wherein a length of the electrical connection between the electrical vacuum feedthrough and the at least one connected actuator/sensor device is at least three times a length of the optical waveguide between the optical transceiver module and the controller.

13. The optical system of claim 1, wherein the vacuum-tight housing comprises an encapsulated region in the vacuum housing.

14. The optical system of claim 1, wherein the optical system is a lithography illumination optics unit.

15. The optical system of claim 1, wherein the optical system is a lithography projection optics unit.

16. The optical system of claim 1, further comprising the controller and the optical waveguide.

17. The optical system of claim 1, wherein the vacuum housing is under vacuum, and the vacuum-tight housing is under atmospheric pressure.

18. An apparatus, comprising:
an optical system according to claim 1,
wherein the apparatus is a lithography apparatus.

19. An arrangement, comprising:
an optical system according to claim 1;
an optical waveguide; and
a controller in a gray room or in a clean room,
wherein the optical transceiver module and the controller are connected to transfer data transfer via the optical waveguide.

20. The arrangement of claim 19, wherein the controller is configured to: i) provide control signals for the actuator/sensor devices; and ii) transfer the control signals to the actuator/sensor devices via the optical waveguide, the optical transceiver module, the electrical vacuum feedthrough and the electrical connection.
